(19) United States
(12) Patent Application Publication
(10) Pub. No.: US 2026/0212946 A1
(43) Pub. Date: Jul. 23, 2026

(54) FAULT MODE REGISTER REPORTING

(71) Applicant: Micron Technology, Inc., Boise, ID (US)

(72) Inventor: Scott E. SCHAEFER, Boise, ID (US)

(21) Appl. No.: 19/395,369

(22) Filed: Nov. 20, 2025

Related U.S. Application Data
(60) Provisional application No. 63/747,684, filed on Jan. 21, 2025.

(51) Int. Cl. G11C 29/44

(52) U.S. Cl. CPC G11C 29/44

(57) ABSTRACT

In some implementations, a memory apparatus may obtain, from a host system, a command indicating that the memory apparatus is to provide data to the host system. The memory apparatus may identify a status of one or more fault mode registers based on the command. The memory apparatus may provide, to the host system, a message comprising the data and comprising the status of the one or more fault mode registers.

### CROSS-REFERENCE TO RELATED APPLICATION

This Patent Application claims priority to U.S. Provisional Patent Application No. 63/747,684, filed on Jan. 21, 2025, entitled “FAULT MODE REGISTER REPORTING,” and assigned to the assignee hereof. The disclosure of the prior Application is considered part of and is incorporated by reference into this Patent Application.

### TECHNICAL FIELD

The present disclosure generally relates to memory devices, memory device operations, and, for example, to fault mode register reporting.

### BACKGROUND

Memory devices are widely used to store information in various electronic devices. A memory device includes memory cells. A memory cell is an electronic circuit capable of being programmed to a data state of two or more data states. For example, a memory cell may be programmed to a data state that represents a single binary value, often denoted by a binary “1” or a binary “0.” As another example, a memory cell may be programmed to a data state that represents a fractional value (e.g., 0.5, 1.5, or the like). To store information, an electronic device may write to, or program, a set of memory cells. To access the stored information, the electronic device may read, or sense, the stored state from the set of memory cells.

Various types of memory devices exist, including random access memory (RAM), read only memory (ROM), dynamic RAM (DRAM), static RAM (SRAM), synchronous dynamic RAM (SDRAM), ferroelectric RAM (FeRAM), magnetic RAM (MRAM), resistive RAM (RRAM), holographic RAM (HRAM), flash memory (e.g., NAND memory and NOR memory), and others. A memory device may be volatile or non-volatile. Non-volatile memory (e.g., flash memory) can store data for extended periods of time even in the absence of an external power source. Volatile memory (e.g., DRAM) may lose stored data over time unless the volatile memory is refreshed by a power source.

### BRIEF DESCRIPTION OF THE DRAWINGS

FIG. 1 is a diagram illustrating an example system capable of fault mode register reporting.

FIG. 2 shows an example of a data packet that supports fault mode register reporting.

FIGS. 3A and 3B are diagrams of an example of fault mode register reporting.

FIG. 4 is a flowchart of an example method associated with fault mode register reporting.

FIG. 5 is a flowchart of an example method associated with fault mode register reporting.

FIG. 6 is a flowchart of an example method associated with fault mode register reporting.

### DETAILED DESCRIPTION

Some memory systems may maintain one or more fault mode registers to track faults associated with a memory system that may occur during operation of the memory system. A fault mode register may be a register within the memory system configured to log one or more error conditions. For example, a fault mode register may include one or more bits, where each bit may indicate whether the memory system has detected a respective error condition. The memory system may maintain multiple fault mode registers, such as a respective one or more fault mode registers for each memory device (e.g., each memory die) of the memory system. In some cases, the memory system may manage an alert mechanism, such as an alert pin and/or an alert flag, among other examples. The memory system may use the alert mechanism to indicate to the host system that at least one error condition has been detected. In response to the alert mechanism indication, the host system may query the memory system to identify information associated with the alert mechanism indication, such as the particular error condition detected by the memory system and/or the memory die associated with the error condition, among other examples. However, such an implementation may be relatively slow (e.g., around 30 nanoseconds), which may result in high latency associated with reporting such errors. High error reporting latency may hinder the ability of the host system to take corrective action, such as by reducing the amount of time available for the host system to attempt to rewrite or otherwise recover the data in the payload. Thus, a high error reporting latency may reduce the reliability of data written to the memory system.

Some implementations described herein enable fault mode register reporting. For example, a memory apparatus and a host system may support a fault monitoring mode. While operating in the fault monitoring mode, the memory apparatus may be configured to report a status of one or more fault mode registers by including the status in a data packet used to communicate data associated with a read command to the host system. The status of the one or more fault mode registers may indicate whether the memory apparatus has detected one or more error conditions. For example, the status may include one or more bits (e.g., flags), where each bit corresponds to a particular error condition. If the memory apparatus detects a particular error condition, then the memory apparatus may set the bit (e.g., store a value, such as a logic “1”) corresponding to the particular error condition.

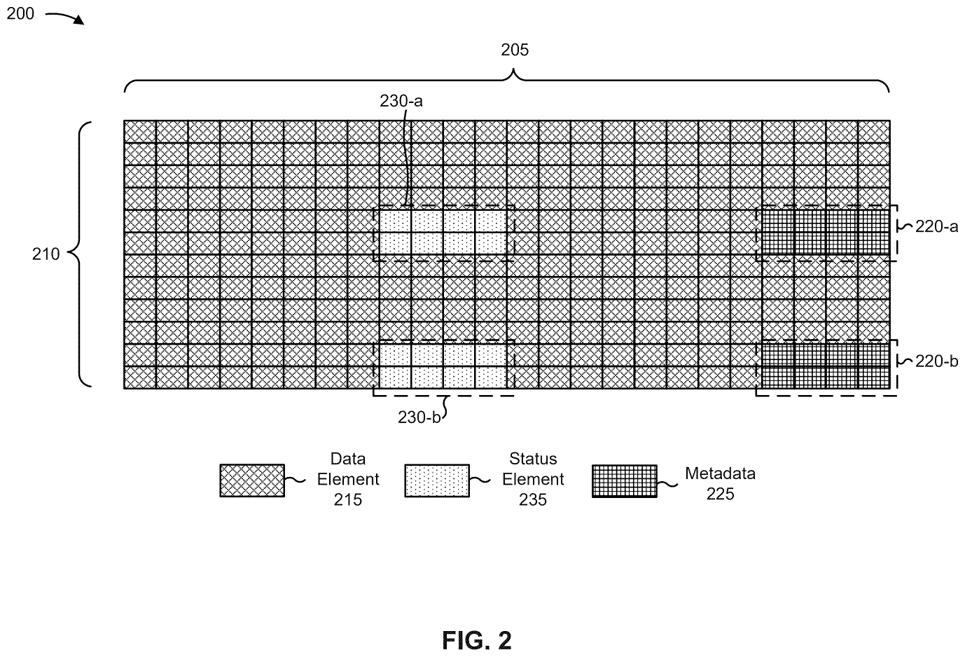

By way of example, the host system may provide, and the memory apparatus may obtain, a read command for data stored to the memory apparatus. Based on, in response to, or otherwise associated with obtaining the read command, the memory apparatus may identify a status of one or more fault mode registers. The memory apparatus may generate a data packet that includes both the data associated with the read command and the status. The memory apparatus may place the status in one or more locations of the data packet provisioned for metadata, as described in greater detail in connection with FIG. 2. The memory apparatus may provide, and the host system may obtain, the data packet.

By enabling fault mode register reporting, the host system and/or the memory apparatus may reduce the latency associated with such reporting. This reduced latency may improve system performance, for example by reducing the time used to recover from errors, thereby maintaining higher throughput levels. Further, such error reporting may improve the ability of the host system to take corrective action, such as by increasing the amount of time available for the host system to attempt to rewrite or otherwise recover the data in the payload. Thus, reduced error reporting latency may increase the reliability of data written to the memory apparatus.

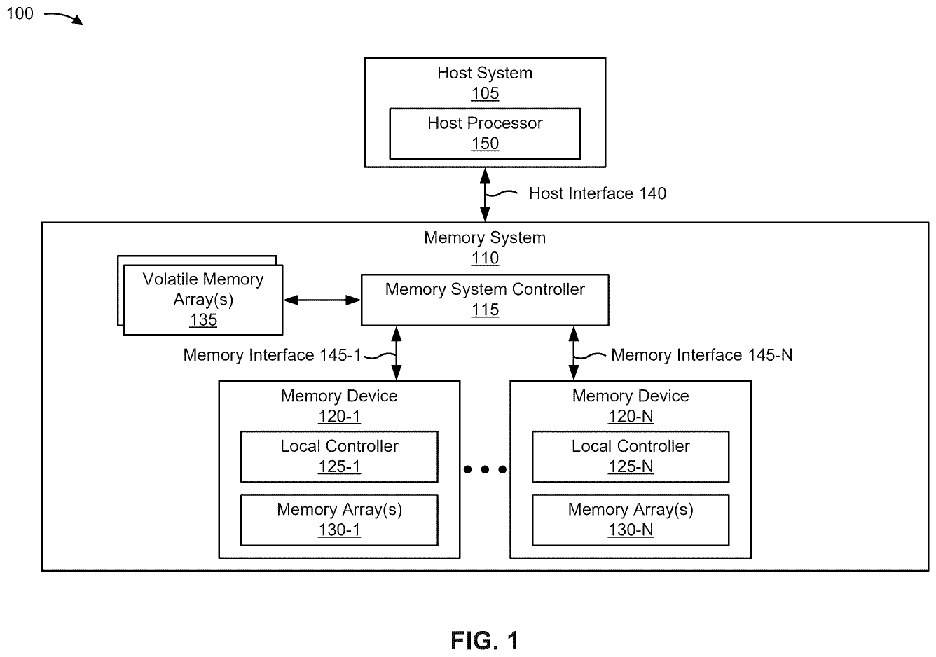

FIG. 1 is a diagram illustrating an example system 100 capable of fault mode register reporting. The system 100 may include one or more devices, apparatuses, and/or components for performing operations described herein. For example, the system 100 may include a host system 105 and a memory system 110. The memory system 110 may include a memory system controller 115 and one or more memory devices 120, shown as memory devices 120-1 through 120-N (where N≥1). A memory device may include a local controller 125 and one or more memory arrays 130. The host system 105 may communicate with the memory system 110 (e.g., the memory system controller 115 of the memory system 110) via a host interface 140. The memory system controller 115 and the memory devices 120 may communicate via respective memory interfaces 145, shown as memory interfaces 145-1 through 145-N (where N≥1).

The system 100 may be any electronic device configured to store data in memory. For example, the system 100 may be a computer, a mobile phone, a wired or wireless communication device, a network device, a server, a device in a data center, a device in a cloud computing environment, a vehicle (e.g., an automobile or an airplane), and/or an Internet of Things (IoT) device. The host system 105 may include a host processor 150. The host processor 150 may include one or more processors configured to execute instructions and store data in the memory system 110. For example, the host processor 150 may include a central processing unit (CPU), a graphics processing unit (GPU), a field-programmable gate array (FPGA), an application-specific integrated circuit (ASIC), and/or another type of processing component.

The memory system 110 may be any electronic device or apparatus configured to store data in memory. For example, the memory system 110 may be a hard drive, a solid-state drive (SSD), a flash memory system (e.g., a NAND flash memory system or a NOR flash memory system), a universal serial bus (USB) drive, a memory card (e.g., a secure digital (SD) card), a secondary storage device, a non-volatile memory express (NVMe) device, an embedded multimedia card (eMMC) device, a dual in-line memory module (DIMM), and/or a random-access memory (RAM) device, such as a dynamic RAM (DRAM) device or a static RAM (SRAM) device.

The memory system controller 115 may be any device configured to control operations of the memory system 110 and/or operations of the memory devices 120. For example, the memory system controller 115 may include control logic, a memory controller, a system controller, an ASIC, an FPGA, a processor, a microcontroller, and/or one or more processing components. In some implementations, the memory system controller 115 may communicate with the host system 105 and may instruct one or more memory devices 120 regarding memory operations to be performed by those one or more memory devices 120 based on one or more instructions from the host system 105. For example, the memory system controller 115 may provide instructions to a local controller 125 regarding memory operations to be performed by the local controller 125 in connection with a corresponding memory device 120.

A memory device 120 may include a local controller 125 and one or more memory arrays 130. In some implementations, a memory device 120 includes a single memory array 130. In some implementations, each memory device 120 of the memory system 110 may be implemented in a separate semiconductor package or on a separate die that includes a respective local controller 125 and a respective memory array 130 of that memory device 120. The memory system 110 may include multiple memory devices 120.

A local controller 125 may be any device configured to control memory operations of a memory device 120 within which the local controller 125 is included (e.g., and not to control memory operations of other memory devices 120). For example, the local controller 125 may include control logic, a memory controller, a system controller, an ASIC, an FPGA, a processor, a microcontroller, and/or one or more processing components. In some implementations, the local controller 125 may communicate with the memory system controller 115 and may control operations performed on a memory array 130 coupled with the local controller 125 based on one or more instructions from the memory system controller 115. As an example, the memory system controller 115 may be an SSD controller, and the local controller 125 may be a NAND controller.

A memory array 130 may include an array of memory cells configured to store data. For example, a memory array 130 may include a non-volatile memory array (e.g., a NAND memory array or a NOR memory array) or a volatile memory array (e.g., an SRAM array or a DRAM array). In some implementations, the memory system 110 may include one or more volatile memory arrays 135. A volatile memory array 135 may include an SRAM array and/or a DRAM array, among other examples. The one or more volatile memory arrays 135 may be included in the memory system controller 115, in one or more memory devices 120, and/or in both the memory system controller 115 and one or more memory devices 120. In some implementations, the memory system 110 may include both non-volatile memory capable of maintaining stored data after the memory system 110 is powered off and volatile memory (e.g., a volatile memory array 135) that requires power to maintain stored data and that loses stored data after the memory system 110 is powered off. For example, a volatile memory array 135 may cache data read from or to be written to non-volatile memory, and/or may cache instructions to be executed by a controller of the memory system 110.

The host interface 140 enables communication between the host system 105 (e.g., the host processor 150) and the memory system 110 (e.g., the memory system controller 115). The host interface 140 may include, for example, a Small Computer System Interface (SCSI), a Serial-Attached SCSI (SAS), a Serial Advanced Technology Attachment (SATA) interface, a Peripheral Component Interconnect Express (PCIe) interface, an NVMe interface, a USB interface, a Universal Flash Storage (UFS) interface, an eMMC interface, a double data rate (DDR) interface, and/or a DIMM interface.

The memory interface 145 enables communication between the memory system 110 and the memory device 120. The memory interface 145 may include a non-volatile memory interface (e.g., for communicating with non-volatile memory), such as a NAND interface or a NOR interface. Additionally, or alternatively, the memory interface 145 may include a volatile memory interface (e.g., for communicating with volatile memory), such as a DDR interface.

Although the example memory system 110 described above includes a memory system controller 115, in some implementations, the memory system 110 does not include a memory system controller 115. For example, an external controller (e.g., included in the host system 105) and/or one or more local controllers 125 included in one or more corresponding memory devices 120 may perform the operations described herein as being performed by the memory system controller 115. Furthermore, as used herein, a “controller” may refer to the memory system controller 115, a local controller 125, or an external controller. In some implementations, a set of operations described herein as being performed by a controller may be performed by a single controller. For example, the entire set of operations may be performed by a single memory system controller 115, a single local controller 125, or a single external controller. Alternatively, a set of operations described herein as being performed by a controller may be performed by more than one controller. For example, a first subset of the operations may be performed by the memory system controller 115 and a second subset of the operations may be performed by a local controller 125. Furthermore, the term “memory apparatus” may refer to the memory system 110 or a memory device 120, depending on the context.

A controller (e.g., the memory system controller 115, a local controller 125, or an external controller) may control operations performed on memory (e.g., a memory array 130), such as by executing one or more instructions. For example, the memory system 110 and/or a memory device 120 may store one or more instructions in memory as firmware, and the controller may execute those one or more instructions. Additionally, or alternatively, the controller may receive one or more instructions from the host system 105 and/or from the memory system controller 115, and may execute those one or more instructions. In some implementations, a non-transitory computer-readable medium (e.g., volatile memory and/or non-volatile memory) may store a set of instructions (e.g., one or more instructions or code) for execution by the controller. The controller may execute the set of instructions to perform one or more operations or methods described herein. In some implementations, execution of the set of instructions, by the controller, causes the controller, the memory system 110, and/or a memory device 120 to perform one or more operations or methods described herein. In some implementations, hardwired circuitry is used instead of or in combination with the one or more instructions to perform one or more operations or methods described herein. Additionally, or alternatively, the controller may be configured to perform one or more operations or methods described herein. An instruction is sometimes called a “command.”

For example, the controller (e.g., the memory system controller 115, a local controller 125, or an external controller) may transmit signals to and/or receive signals from memory (e.g., one or more memory arrays 130) based on the one or more instructions, such as to transfer data to (e.g., write or program), to transfer data from (e.g., read), to erase, and/or to refresh all or a portion of the memory (e.g., one or more memory cells, pages, sub-blocks, blocks, or planes of the memory). Additionally, or alternatively, the controller may be configured to control access to the memory and/or to provide a translation layer between the host system 105 and the memory (e.g., for mapping logical addresses to physical addresses of a memory array 130). In some implementations, the controller may translate a host interface command (e.g., a command received from the host system 105) into a memory interface command (e.g., a command for performing an operation on a memory array 130).

In some implementations, one or more systems, devices, apparatuses, components, and/or controllers of FIG. 1 may be configured to obtain, from a host system, a command indicating that the memory apparatus is to provide data to the host

system; identify a status of one or more fault mode registers based on the command; and provide, to the host system, a message comprising the data and comprising the status of the one or more fault mode registers.

In some implementations, one or more systems, devices, apparatuses, components, and/or controllers of FIG. 1 may be configured to provide, to a memory apparatus, a read command for data stored to the memory apparatus; and obtain, from the memory apparatus, a message comprising the data and comprising a status of one or more fault mode registers of the memory apparatus.

In some implementations, one or more systems, devices, apparatuses, components, and/or controllers of FIG. 1 may include a host system; a memory apparatus; a host interface between the host system and the memory apparatus; and one or more components configured to communicate, via the host interface and to the memory apparatus, a command indicating that the memory apparatus is to provide data to the host system; identify a status of one or more fault mode registers based on the command; and communicate, via the host interface and to the host system, a message comprising the data and comprising the status of the one or more fault mode registers.

The number and arrangement of components shown in FIG. 1 are provided as an example. In practice, there may be additional components, fewer components, different components, or differently arranged components than those shown in FIG. 1. Furthermore, two or more components shown in FIG. 1 may be implemented within a single component, or a single component shown in FIG. 1 may be implemented as multiple, distributed components. Additionally, or alternatively, a set of components (e.g., one or more components) shown in FIG. 1 may perform one or more operations described as being performed by another set of components shown in FIG. 1.

FIG. 2 shows an example of a data packet 200 that supports fault mode register reporting. The data packet 200 illustrates a format of signaling communicated between a host system (e.g., the host system 105) and a memory apparatus (e.g., the memory system 110, one or more memory devices 120) specified by a communication protocol, such as a format used for a burst operation (e.g., a write burst operation and/or a read burst operation).

The data packet 200 may include one or more elements arranged according to one or more time intervals 205, which may be referred to as “beats”, and one or more pins 210 of a bus (e.g., a host interface 140) between the host system and the memory apparatus. Said another way, each pin 210 of the bus may communicate a single element between the host system and the memory system during each time interval 205. An element corresponding to a given time interval 205 and a given pin 210 may represent a voltage level of the given pin 210 during the given time interval 205. For example, an element may be a single bit, such as a high state (e.g., a logic “1”) or a low state (e.g., a logic “0”) at an edge (e.g., a rising edge, a falling edge) of a clock signal used as part of binary signaling. Additionally, or alternatively, an element may correspond to a voltage level of other signaling schemes, such as non-return-to-zero (NRZ) signaling, three-level pulse-amplitude modulation (PAM-3) signaling, and/or PAM-4 signaling, among other examples.

The one or more elements may include one or more data elements 215. The one or more data elements 215 of the data packet may represent the payload of the data packet 200, such as user data communicated between the host system and the memory system.

In some examples, the communication protocol may specify one or more locations 220 (e.g., one or more subsets of the time intervals 205 and/or the pins 210, one or more portions of the data packet 200) within the data packet 200 to include metadata associated with the payload of the data packet 200. For example, the communication protocol may specify that metadata may be included at a location 220-a and/or a location 220-b, as illustrated in FIG. 2. Said another way, the communication protocol may provision the locations 220 for metadata. In some cases, the host system may place one or more metadata elements 225 in the locations 220. For example, if the data packet 200 is associated with a write command, then the host system may include additional parity information or other system metadata to improve the reliability of the data packet 200. The memory system may be configured to store the metadata to one or more memory arrays provisioned for metadata associated with the payload.

The host system and/or the memory apparatus may support a fault monitoring mode. While operating in the fault monitoring mode, the memory apparatus may be configured to report a status of one or more fault mode registers by including the status in the data packet 200. A fault mode register may be a register within the memory system configured to log one or more error conditions. For example, a fault mode register may include one or more values (e.g., binary indicators, flags), where each value may indicate whether the memory apparatus has detected an error condition corresponding to the value. If the memory apparatus detects a particular error

condition, then the memory apparatus may set the bit (e.g., store a value, such as a logic “1”) corresponding to the particular error condition.

In some implementations, the memory apparatus may continually monitor for the one or more error conditions. For example, the memory apparatus may be configured to periodically perform one or more memory management or other health monitoring operations to detect the one or more error conditions. Additionally, the memory apparatus may initialize the one or more fault mode registers, such as during a power-on operation. To initialize the one or more fault mode registers, the memory apparatus may store one or more initial values, such as one or more “0” values, to the one or more fault mode registers.

The one or more error conditions may include a row hammer condition, such as a PRAC (protected row activation count) condition. A row hammer condition may occur if the memory apparatus performs multiple row activation operations without performing a refresh operation on one or more rows of memory cells. Accordingly, if the memory apparatus determines that a quantity of row activation commands satisfies a threshold (e.g., without an intervening refresh operation), then the memory apparatus may store a value to the one or more fault mode registers indicating the row hammer condition.

The one or more error conditions may include a write link error correction code (ECC) error condition. A write link ECC error condition may occur if the memory apparatus detects one or more errors (e.g., single-bit errors and/or multi-bit errors) in data obtained from the host system as part of a write operation. In some examples, if the memory apparatus determines that the one or more errors cannot be corrected, then the memory apparatus may store a value to the one or more fault mode registers indicating the write link ECC error condition.

The one or more error conditions may include an on-die ECC error threshold fault condition. An on-die ECC error threshold fault condition may occur if the memory apparatus detects that a quantity and/or rate of errors (single-bit errors and/or multi-bit errors) satisfies a threshold. Thus, if the memory apparatus determines that the quantity of errors satisfies the threshold, then the memory apparatus may store a value to the one or more fault mode registers indicating the on-die ECC error threshold fault condition.

The one or more error conditions may include a command/address (CA) parity fault condition. A CA parity fault condition may occur if the memory apparatus detects an error in a command and/or address obtained from the host system (e.g., using parity information included in or associated with the command and/or the address). Thus, if the memory apparatus detects an error in a command and/or an address, then the memory apparatus may store a value to the one or more fault mode registers indicating the CA parity fault condition.

The one or more error conditions may include a refresh rate change condition. A refresh rate change condition may indicate a change in the refresh rate (e.g., the rate at which refresh operations are performed by the memory apparatus, such as a frequency of refresh operations) of the memory apparatus. Such a change may result from temperature changes or other environmental factors. Thus, if the memory apparatus determines that the refresh rate has changed (e.g., by a threshold amount), then the memory apparatus may store a value to the one or more fault mode registers indicating the refresh rate change condition.

By way of example, based on, in response to, or otherwise associated with a read command from the host system, the memory apparatus may identify the status of the one or more fault mode registers. The memory apparatus may generate the data packet 200 to include both the data associated with the read command (e.g., as one or more data elements 215) and the status. The memory apparatus may place the status in one or more locations 230 (e.g., a location 230-a and/or a location 230-b) of the data packet 200. For example, the memory apparatus may place each value of the status (e.g., each bit, each flag) in a status element 235 of the one or more locations 230. Additionally, or alternatively, the memory apparatus may place the status in the one or more locations 220.

In some examples, the memory apparatus may selectively include a subset of the values of the status in the data packet 200 based on a status configuration. As used herein, “selectively” performing an operation means to either perform the operation or refrain from performing the operation. For example, selectively performing an operation based on whether a condition is satisfied means that the operation is performed if the condition is satisfied and that the operation is not performed if the condition is not satisfied (or vice versa). Thus, selectively performing an operation may include determining whether to perform the operation and then either performing the operation or refraining from performing the operation based on that determination. As used herein, “selectively” performing a first operation or a second operation means to perform either the first operation or the second operation. For example, selectively performing a first operation or a second operation based on whether a condition is satisfied means that the first operation is performed if the condition is satisfied and that the second operation is performed if the condition is not satisfied (or vice versa). Thus, selectively performing a first operation or a second operation may include determining whether to perform either the first operation or the second operation and then performing either the first operation or the second operation based on that determination.

For example, the host system may provide a status configuration to indicate one or more first error conditions (e.g., a particular subset of the values of the status) to be included in the data packet 200. In such an example, to generate the data packet 200, the memory apparatus may include the values corresponding to the one or more first error conditions in the status, and may not include values corresponding to other error conditions in the status. Additionally, or alternatively, the status configuration may indicate one or more second error conditions to not be included in the data packet 200. In such an example, to generate the data packet 200, the memory apparatus may not include the values corresponding to the one or more second error conditions in the status, and may include values corresponding to other error conditions in the status.

In some examples, the memory apparatus may selectively place the status in the location 220-a, the location 220-b, the location 230-a, and/or the location 230-b based on a location configuration. For example, the host system may provide a location configuration to indicate a particular one or more locations (e.g., a location 220) within the data packet 200 in which the memory apparatus is to place the status. By way of example, the host system may provide a location configuration to indicate that the memory apparatus is to place the status in the location 220-a and/or the location 220-b. In such an example, to generate the data packet 200, the memory apparatus may place the status in the location 220-a and/or the location 220-b.

Additionally, or alternatively, the memory apparatus may be configured to place the status in a default location, such as the location 230-a and/or the location 230-b. The memory apparatus may use the default location unless otherwise instructed by the host system. Said another way, if the memory apparatus does not obtain a location configuration from the host system, then, to generate the data packet 200, the memory apparatus may place the status in the location 230-a and/or the location 230-b.

As indicated above, FIG. 2 is provided as an example. Other examples may differ from what is described with regard to FIG. 2.

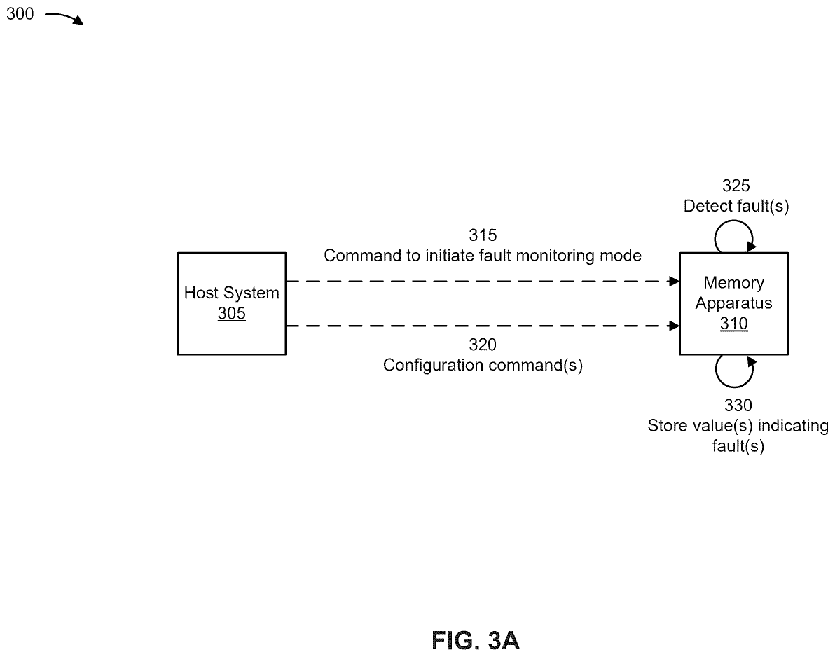

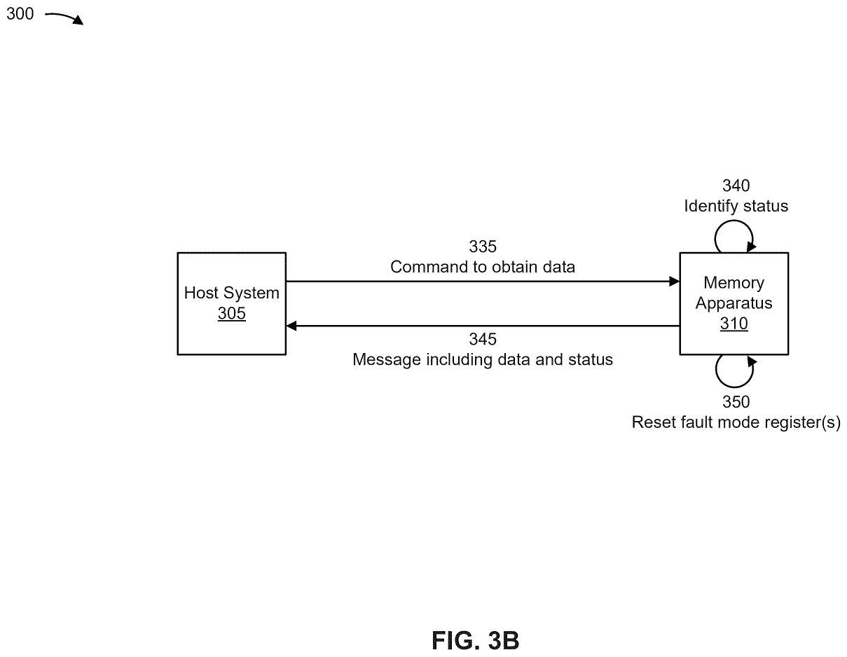

FIGS. 3A and 3B are diagrams of an example 300 of fault mode register reporting. The operations described in connection with FIGS. 3A and 3B may be performed by a system, such as the system 100 and/or one or more components thereof, such as the host system 105, the host interface 140, the memory system 110, the memory system controller 115, one or more memory devices 120, and/or one or more local controllers 125.

As shown in FIGS. 3A and 3B, the example 300 may include a host system 305 and a memory apparatus 310. The host system 305 may be the host system 105. The memory apparatus 310 may be or may include the memory system 110, one or more memory devices 120, and/or one or more controllers (e.g., the memory system controller 115 and/or one or more local controllers 125).

The example 300 illustrates a process to enable the host system 305 and the memory apparatus 310 to operate in a fault monitoring mode. While operating in the fault monitoring mode, the memory apparatus 310 may be configured to report the status of one or more fault mode registers by including the status in a data packet (e.g., a data packet 200) used to communicate data associated with a read command to the host system 305. For example, as shown by reference number 315, the host system 305 may provide, and the memory apparatus 310 may obtain, a command indicating that the memory apparatus 310 is to operate in the fault monitoring mode. In some examples, the memory apparatus 310 may store a value indicative of the fault monitoring mode, such as by setting a flag of (e.g., writing a logical “1” to) one or more mode registers. In such examples, the command may be a mode register write command.

In some implementations, as shown by reference number 320, the host system 305 may provide, and the memory apparatus 310 may obtain, one or more configuration commands. The one or more configuration commands may indicate one or more configurations for the fault monitoring mode. For example, the one or more configuration commands may include a status configuration command indicating one or more error conditions to be included in the status. By way of example, the status configuration command may indicate that a first subset of the one or more error conditions are to be included in the status, and that a second subset of the one or more error conditions are not to be included in the status. The memory apparatus 310 may store a value indicative of the status configuration, such as by storing the value to one or more mode registers.

Additionally, or alternatively, the one or more configuration commands may include a location command indicating a location configuration. The location configuration may indicate a location (e.g., a location 220) within the data packet in which the memory apparatus 310 is to place the status. The memory apparatus 310 may store a value indicative of the location configuration, such as by storing the value to one or more mode registers.

Additionally, or alternatively, the one or more configuration commands may include a delay command indicating a delay configuration. The delay configuration may indicate information associated with a delay to be used as part of reporting the status. For example, the delay configuration may indicate a duration (e.g., a length) of the delay, and/or a quantity of clock cycles, as described in further detail in connection with reference number 345. The memory apparatus 310 may store a value indicative of the delay configuration, such as by storing the value to one or more mode registers.

As shown by reference number 325, the memory apparatus 310 may detect one or more error conditions associated with the memory apparatus. For example, the memory apparatus 310 may monitor one or more operational parameters and/or error conditions, such as row hammer events, write link ECC errors, on-die ECC errors, command/address parity faults, and/or refresh rate changes. As shown by reference number 330, based on, in response to, or otherwise associated with determining that a particular error condition has occurred, the memory apparatus 310 may store a value to the one or more fault mode registers indicating the particular error condition. In some implementations, the memory apparatus 310 may continually monitor for the one or more error conditions. For example, the memory apparatus 310 may be configured to periodically perform one or more memory management or other health monitoring operations to detect the one or more error conditions.

As shown in FIG. 3B, and by reference number 335, the host system 305 may provide, and the memory apparatus 310 may obtain, a command indicating that the memory apparatus is to provide data to the host system. The command may be a read command. The host system 305 may issue the read command to retrieve specific data stored in the memory apparatus 310. Based on, in response to, or otherwise associated with obtaining the read command, the memory apparatus 310 may retrieve the data (e.g., from one or more memory arrays).

As shown by reference number 340, based on, in response to, or otherwise associated with obtaining the read command, the memory apparatus 310 may identify a status of the one or more fault mode registers. For example, the memory apparatus 310 may read the one or more fault mode registers.

In some implementations, the read command may correspond to a particular memory device (e.g., a particular memory die) within the memory apparatus 310. In such examples, the message may include the status of the one or more fault mode registers associated with the particular memory device. Additionally, the message may not include the status of fault mode registers corresponding to other memory devices.

As shown by reference number 345, the memory apparatus 310 may provide, and the host system 305 may obtain, a message that includes the data associated with the read command and the status of the one or more fault mode registers. For example, based on the memory apparatus 310 operating in the fault monitoring mode, the memory apparatus 310 may place the status in one or more locations of the message.

In some examples, the memory apparatus 310 may selectively include a first subset of the values of the status in the message based on a status configuration. For example, if the status configuration indicates that the first subset of the values is to be included in the message, then the memory apparatus 310 may place the first subset of values in the message, and may refrain from placing a second subset of values of the status in the message.

In some implementations, the memory apparatus 310 may selectively place the status in a particular location based on the location configuration. For example, if the location configuration indicates a first location, then the memory apparatus 310 may place the status in the first location and may refrain from placing the status in one or more second locations.

In some implementations, the memory apparatus 310 may delay one or more aspects of the example 300 based on the delay configuration. For example, if the delay configuration indicates a particular duration, then the memory apparatus 310 may delay identifying the status and/or providing the message for the duration. The memory apparatus 310 may use the additional time provided by the delay to perform one or more error condition detecting operations, such as identifying errors using on-die ECC or otherwise ensuring an accurate status of the one or more fault mode registers.

Additionally, or alternatively, the memory apparatus 310 may be configured to adaptively change the duration of and/or disable the delay based on operating conditions of the memory apparatus 310, such as power usage, temperature, or other environmental factors. For example, if the memory apparatus 310 is operating in a high-performance mode, then the memory apparatus 310 may shorten and/or remove the delay, which may reduce latency associated with the read command (e.g., at the cost of increased power consumption). Alternatively, if the memory apparatus 310 is operating in a power-saving mode, then the memory apparatus 310 may increase the delay duration, which may allow for more accurate error detection while reducing power usage (e.g., at the cost of increased latency).

By including the status in the message, the host system 305 and/or the memory apparatus 310 may reduce the latency associated with reporting the status of the one or more fault mode registers. This reduced latency may improve system performance, for example by reducing the time used to recover from errors, thereby maintaining higher throughput levels. Further, such error reporting may improve the ability of the host system 305 to take corrective action, such as by increasing the amount of time available for the host system 305 to attempt to rewrite or otherwise recover the data in the message. Thus, reduced error reporting latency may increase the reliability of data written to the memory apparatus 310.

As shown by reference number 350, the memory apparatus 310 may reset the one or more fault mode registers. Resetting the one or more fault mode registers may include storing one or more values (e.g., an initial value, such as one or more logical “0” values) to the one or more fault mode registers. In some implementations, the memory apparatus 310 may be configured to reset the one or more fault mode registers after notifying the host system 305 of the status of the one or more fault mode registers. For example, based on, in response to, or otherwise associated with providing the message to the host system 305, the memory apparatus 310 may reset the one or more fault mode registers. Additionally, or alternatively, the memory apparatus 310 may be configured to reset the one or more fault mode registers based on an instruction from the host system 305. For example, the host system 305 may provide, and the memory apparatus 310 may obtain, a reset command indicating that the memory apparatus is to reset the one or more fault mode registers. Based on, in response to, or otherwise associated with obtaining the reset command, the memory apparatus 310 may reset the one or more fault mode registers.

As indicated above, FIGS. 3A and 3B are provided as an example. Other examples may differ from what is described with regard to FIGS. 3A and 3B.

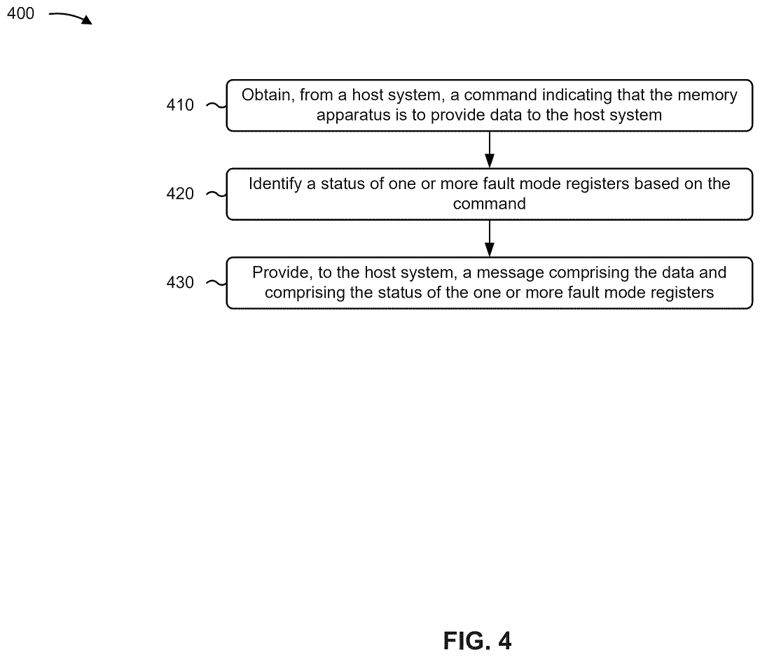

FIG. 4 is a flowchart of an example method 400 associated with fault mode register reporting. In some implementations, a memory apparatus (e.g., the memory system 110 and/or the memory apparatus 310) may perform or may be configured to perform the method 400. In some implementations, another device or a group of devices separate from or including the memory apparatus (e.g., the host system 105, the host system 305, and/or the host interface 140) may perform or may be configured to perform the method 400. Additionally, or alternatively, one or more components of the memory apparatus (e.g., the memory system controller 115, one or more memory devices 120, one or more local controllers 125, one or more memory arrays 130, one or more volatile memory arrays 135, and/or one or more memory interfaces 145) may perform or may be configured to perform the method 400. Thus, means for performing the method 400 may include the memory apparatus and/or one or more components of the memory apparatus. Additionally, or alternatively, a non-transitory computer-readable medium may store one or more instructions that, when executed by the memory apparatus, cause the memory apparatus to perform the method 400.

As shown in FIG. 4, the method 400 may include obtaining, from a host system, a command indicating that the memory apparatus is to provide data to the host system (block 410). As further shown in FIG. 4, the method 400 may include identifying a status of one or more fault mode registers based on the command (block 420). As further shown in FIG. 4, the method 400 may include providing, to the host system, a message comprising the data and comprising the status of the one or more fault mode registers (block 430).

The method 400 may include additional aspects, such as any single aspect or any combination of aspects described below and/or described in connection with one or more other methods or operations described elsewhere herein.

In a first aspect, the method 400 includes detecting one or more faults associated with the memory apparatus, and storing, to the one or more fault mode registers, respective values indicating the one or more faults, wherein the status of the one or more fault mode registers is based on the respective values.

In a second aspect, alone or in combination with the first aspect, the method 400 includes obtaining, from the host system, a configuration command associated with the one or more fault mode registers, and selectively including, based on the configuration command, a subset of the respective values in the message.

In a third aspect, alone or in combination with one or more of the first and second aspects, providing the message to the host system comprises providing a portion of the data via a pin of one or more pins of a bus between the host system and the memory apparatus, and providing a portion of the status via the pin.

In a fourth aspect, alone or in combination with one or more of the first through third aspects, the method 400 includes obtaining, from the host system, another command to initiate a fault monitoring mode, and storing a value indicating the fault monitoring mode to one or more mode registers of the memory apparatus, wherein identification of the status is based on the value indicating the fault monitoring mode.

In a fifth aspect, alone or in combination with one or more of the first through fourth aspects, the method 400 includes obtaining, from the host system, another command indicating a location configuration for the status, and storing a value indicating the location configuration to one or more mode registers of the memory apparatus.

In a sixth aspect, alone or in combination with one or more of the first through fifth aspects, providing the message to the host system comprises selectively placing, based on the location configuration, the status in a first location of the message or place the status in a second location of the message.

In a seventh aspect, alone or in combination with one or more of the first through sixth aspects, the method 400 includes delaying, based on a delay configuration that indicates a duration, the message for the duration.

In an eighth aspect, alone or in combination with one or more of the first through seventh aspects, the method 400 includes obtaining, from the host system, another command indicating the delay configuration, and storing a value indicating the delay configuration to one or more mode registers of the memory apparatus.

In a ninth aspect, alone or in combination with one or more of the first through eighth aspects, the method 400 includes resetting the one or more fault mode registers based on provision of the message.

In a tenth aspect, alone or in combination with one or more of the first through ninth aspects, the method 400 includes obtaining, from the host system, another command indicating that the memory apparatus is to reset the one or more fault mode registers, and resetting, based on the other command, the one or more fault mode registers.

In an eleventh aspect, alone or in combination with one or more of the first through tenth aspects, the method 400 includes initializing the one or more fault mode registers as part of a power-on operation.

In a twelfth aspect, alone or in combination with one or more of the first through eleventh aspects, the message comprises a data burst packet.

Although FIG. 4 shows example blocks of a method 400, in some implementations, the method 400 may include additional blocks, fewer blocks, different blocks, or differently arranged blocks than those depicted in FIG. 4. Additionally, or alternatively, two or more of the blocks of the method 400 may be performed in parallel. The method 400 is an example of one method that may be performed by one or more devices described herein. These one or more devices may perform or may be configured to perform one or more other methods based on operations described herein.

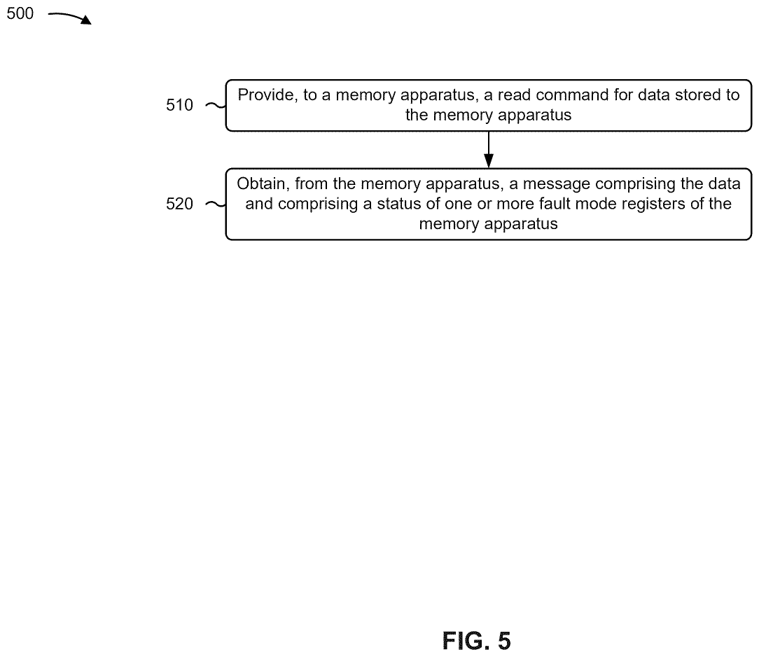

FIG. 5 is a flowchart of an example method 500 associated with fault mode register reporting. In some implementations, a host system (e.g., the host system 105 and/or the host system 305) may perform or may be configured to perform the method 500. In some implementations, another device or a group of devices separate from or including the host system (e.g., the memory system 110, the host interface 140, and/or the memory apparatus 310) may perform or may be configured to perform the method 500. Additionally, or alternatively, one or more components of the host system (e.g., the host processor 150) may perform or may be configured to perform the method 500. Thus, means for performing the method 500 may include the host system and/or one or more components of the host system. Additionally, or alternatively, a non-transitory computer-readable medium may store one or more instructions that, when executed by the host system, cause the host system to perform the method 500.

As shown in FIG. 5, the method 500 may include providing, to a memory apparatus, a read command for data stored to the memory apparatus (block 510). As further shown in FIG. 5, the method 500 may include obtaining, from the memory apparatus, a message comprising the data and comprising a status of one or more fault mode registers of the memory apparatus (block 520).

The method 500 may include additional aspects, such as any single aspect or any combination of aspects described below and/or described in connection with one or more other methods or operations described elsewhere herein.

In a first aspect, the method 500 includes providing, to the memory apparatus, another command to initiate a fault monitoring mode of the memory apparatus, wherein obtainment of the status is based on the other command.

In a second aspect, alone or in combination with the first aspect, obtaining the message from the memory apparatus comprises obtaining a portion of the data via a pin of one or more pins of a bus between the host system and the memory apparatus, and obtaining a portion of the status via the pin.

In a third aspect, alone or in combination with one or more of the first and second aspects, the method 500 includes providing, to the memory apparatus, another command indicating a location configuration for the status, wherein the other command further indicates that the memory apparatus is to store a value indicating the location configuration to one or more mode registers of the memory apparatus.

In a fourth aspect, alone or in combination with one or more of the first through third aspects, the method 500 includes providing, to the memory apparatus, another command indicating that the memory apparatus is to reset the one or more fault mode registers.

In a fifth aspect, alone or in combination with one or more of the first through fourth aspects, the message comprises a data burst packet.

Although FIG. 5 shows example blocks of a method 500, in some implementations, the method 500 may include additional blocks, fewer blocks, different blocks, or differently arranged blocks than those depicted in FIG. 5. Additionally, or alternatively, two or more of the blocks of the method 500 may be performed in parallel. The method 500 is an example of one method that may be performed by one or more devices described herein. These one or more devices may perform or may be configured to perform one or more other methods based on operations described herein.

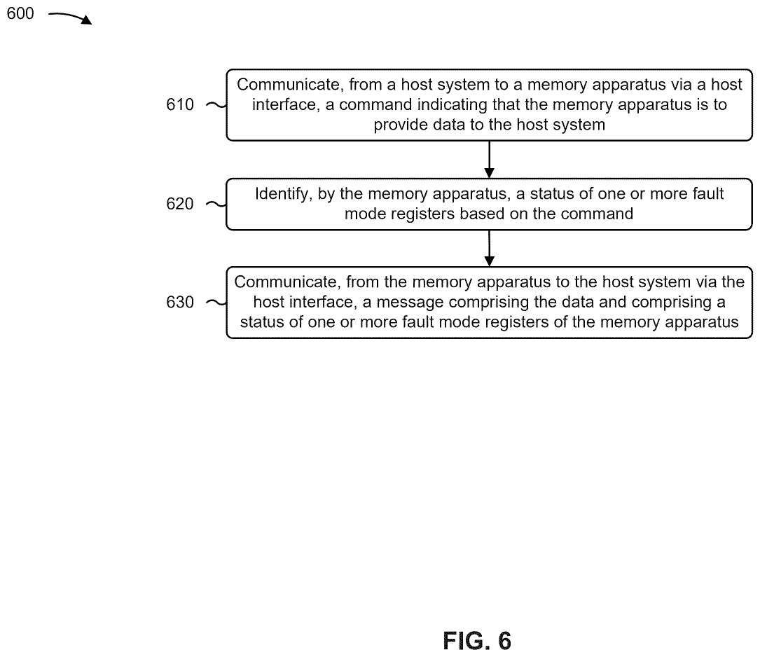

FIG. 6 is a flowchart of an example method 600 associated with fault mode register reporting. In some implementations, a system (e.g., the system 100) may perform or may be configured to perform the method 600. In some implementations, another device or a group of devices separate from or including the system (e.g., the host system 305 and/or the memory apparatus 310) may perform or may be configured to perform the method 600. Additionally, or alternatively, one or more components of the system (e.g., the host system 105, the host interface 140, and/or the memory system 110) may perform or may be configured to perform the method 600. Thus, means for performing the method 600 may include the system and/or one or more components of the system. Additionally, or alternatively, a non-transitory computer-readable medium may store one or more instructions that, when executed by the system, cause the system to perform the method 600.

As shown in FIG. 6, the method 600 may include communicating, from a host system and to a memory apparatus via a host interface, a command indicating that the memory apparatus is to provide data to a host system (block 610). As further shown in FIG. 6, the method 600 may include identifying a status of one or more fault mode registers based on the command (block 620). As further shown in FIG. 6, the method 600 may include communicating, from the memory apparatus to the host system via the host interface, a message comprising the data and comprising the status of the one or more fault mode registers (block 630).

The method 600 may include additional aspects, such as any single aspect or any combination of aspects described below and/or described in connection with one or more other methods or operations described elsewhere herein.

In a first aspect, the method 600 includes detecting one or more faults associated with the memory apparatus, and storing, to the one or more fault mode registers, respective values indicating the one or more faults, wherein the status of the one or more fault mode registers is based on the respective values.

In a second aspect, alone or in combination with the first aspect, the method 600 includes communicating, via the host interface and to the memory apparatus, a configuration command associated with the one or more fault mode registers, and selectively including, based on the configuration command, a subset of the respective values in the message.

In a third aspect, alone or in combination with one or more of the first and second aspects, communicating the message comprises communicating a portion of the data via a pin of one or more pins of the host interface, and communicating a portion of the status via the pin.

In a fourth aspect, alone or in combination with one or more of the first through third aspects, the method 600 includes communicating, via the host interface and to the memory apparatus, another command to initiate a fault monitoring mode, and storing a value indicating the fault monitoring mode to one or more mode registers of the memory apparatus, wherein identification of the status is based on the value indicating the fault monitoring mode.

In a fifth aspect, alone or in combination with one or more of the first through fourth aspects, the method 600 includes communicating, via the host interface and to the memory apparatus, another command indicating a location configuration for the status, and storing a value indicating the location configuration to one or more mode registers of the memory apparatus.

Although FIG. 6 shows example blocks of a method 600, in some implementations, the method 600 may include additional blocks, fewer blocks, different blocks, or differently arranged blocks than those depicted in FIG. 6. Additionally, or alternatively, two or more of the blocks of the method 600 may be performed in parallel. The method 600 is an example of one method that may be performed by one or more devices described herein. These one or more devices may perform or may be configured to perform one or more other methods based on operations described herein.

In some implementations, a memory apparatus includes one or more components configured to: obtain, from a host system, a command indicating that the memory apparatus is to provide data to the host system; identify a status of one or more fault mode registers based on the command; and provide, to the host system, a message comprising the data and comprising the status of the one or more fault mode registers.

In some implementations, a host system includes one or more components configured to: provide, to a memory apparatus, a read command for data stored to the memory apparatus; and obtain, from the memory apparatus, a message comprising the data and comprising a status of one or more fault mode registers of the memory apparatus.

In some implementations, a system includes a host system, a memory apparatus, a host interface between the host system and the memory apparatus, and one or more components configured to: communicate, via the host interface and to the memory apparatus, a command indicating that the memory apparatus is to provide data to the host system; identify, by the memory apparatus, a status of one or more fault mode registers based on the command; and communicate, via the host interface and to the host system, a message comprising the data and comprising the status of the one or more fault mode registers.

The foregoing disclosure provides illustration and description but is not intended to be exhaustive or to limit the implementations to the precise forms disclosed. Modifications and variations may be made in light of the above disclosure or may be acquired from practice of the implementations described herein.

As used herein, “satisfying a threshold” may, depending on the context, refer to a value being greater than the threshold, greater than or equal to the threshold, less than the threshold, less than or equal to the threshold, equal to the threshold, not equal to the threshold, or the like.

Even though particular combinations of features are recited in the claims and/or disclosed in the specification, these combinations are not intended to limit the disclosure of implementations described herein. Many of these features may be combined in ways not specifically recited in the claims and/or disclosed in the specification. For example, the disclosure includes each dependent claim in a claim set in combination with every other individual claim in that claim set and every combination of multiple claims in that claim set. As used herein, a phrase referring to “at least one of” a list of items refers to any combination of those items, including single members. As an example, “at least one of: a, b, or c” is intended to cover a, b, c, a+b, a+c, b+c, and a+b+c, as well as any combination with multiples of the same element (e.g., a+a, a+a+a, a+a+b, a+a+c, a+b+b, a+c+c, b+b, b+b+b, b+b+c, c+c, and c+c+c, or any other ordering of a, b, and c).

When “a component” or “one or more components” (or another element, such as “a controller” or “one or more controllers”) is described or claimed (within a single claim or across multiple claims) as performing multiple operations or being configured to perform multiple operations, this language is intended to broadly cover a variety of architectures and environments. For example, unless explicitly claimed otherwise (e.g., via the use of “first component” and “second component” or other language that differentiates components in the claims), this language is intended to cover a single component performing or being configured to perform all of the operations, a group of components collectively performing or being configured to perform all of the operations, a first component performing or being configured to perform a first operation and a second component performing or being configured to perform a second operation, or any combination of components performing or being configured to perform the operations. For example, when a claim has the form “one or more components configured to: perform X; perform Y; and perform Z,” that claim should be interpreted to mean “one or more components configured to perform X; one or more (possibly different) components configured to perform Y; and one or more (also possibly different) components configured to perform Z.”

No element, act, or instruction used herein should be construed as critical or essential unless explicitly described as such. Also, as used herein, the articles “a” and “an” are intended to include one or more items and may be used interchangeably with “one or more.” Further, as used herein, the article “the” is intended to include one or more items referenced in connection with the article “the” and may be used

interchangeably with “the one or more.” Where only one item is intended, the phrase “only one,” “single,” or similar language is used. Also, as used herein, the terms “has,” “have,” “having,” or the like are intended to be open-ended terms that do not limit an element that they modify (e.g., an element “having” A may also have B). Further, the phrase “based on” is intended to mean “based, at least in part, on” unless explicitly stated otherwise. As used herein, the term “multiple” can be replaced with “a plurality of” and vice versa. Also, as used herein, the term “or” is intended to be inclusive when used in a series and may be used interchangeably with “and/or,” unless explicitly stated otherwise (e.g., if used in combination with “either” or “only one of”).

What is claimed is:

1. A memory apparatus, comprising:
one or more components configured to:
obtain, from a host system, a command indicating that the memory apparatus is to provide data to the host system;
identify a status of one or more fault mode registers based on the command; and
provide, to the host system, a message comprising the data and comprising the status of the one or more fault mode registers.

2. The memory apparatus of claim 1, wherein the one or more components are further configured to:
detect one or more faults associated with the memory apparatus; and
store, to the one or more fault mode registers, respective values indicating the one or more faults, wherein the status of the one or more fault mode registers is based on the respective values.

3. The memory apparatus of claim 2, wherein the one or more components are further configured to:
obtain, from the host system, a configuration command associated with the one or more fault mode registers; and
selectively, based on the configuration command, include a subset of the respective values in the message.

4. The memory apparatus of claim 1, wherein, to provide the message to the host system, the one or more components are configured to:
provide a portion of the data via a pin of one or more pins of a bus between the host system and the memory apparatus; and
provide a portion of the status via the pin.

5. The memory apparatus of claim 1, wherein the one or more components are configured to:
obtain, from the host system, another command to initiate a fault monitoring mode; and
store a value indicating the fault monitoring mode to one or more mode registers of the memory apparatus, wherein identification of the status is based on the value indicating the fault monitoring mode.

6. The memory apparatus of claim 1, wherein the one or more components are configured to:
obtain, from the host system, another command indicating a location configuration for the status; and
store a value indicating the location configuration to one or more mode registers of the memory apparatus.

7. The memory apparatus of claim 6, wherein, to provide the message to the host system, the one or more components are configured to:
selectively, based on the location configuration, place the status in a first location of the message or place the status in a second location of the message.

8. The memory apparatus of claim 1, wherein the one or more components are further configured to:
delay, based on a delay configuration that indicates a duration, the message for the duration.

9. The memory apparatus of claim 8, wherein the one or more components are further configured to:
obtain, from the host system, another command indicating the delay configuration; and
store a value indicating the delay configuration to one or more mode registers of the memory apparatus.

10. The memory apparatus of claim 1, wherein the one or more components are further configured to:
reset the one or more fault mode registers based on provision of the message.

11. The memory apparatus of claim 1, wherein the one or more components are further configured to:
obtain, from the host system, another command indicating that the memory apparatus is to reset the one or more fault mode registers; and
reset, based on the other command, the one or more fault mode registers.

12. The memory apparatus of claim 1, wherein the one or more components are further configured to:
initialize the one or more fault mode registers as part of a power-on operation.

13. The memory apparatus of claim 1, wherein the message comprises a data burst packet.

14. A host system, comprising:
one or more components configured to:
provide, to a memory apparatus, a read command for data stored to the memory apparatus; and
obtain, from the memory apparatus, a message comprising the data and comprising a status of one or more fault mode registers of the memory apparatus.

15. The host system of claim 14, wherein the one or more components are further configured to:
provide, to the memory apparatus, another command to initiate a fault monitoring mode of the memory apparatus, wherein obtainment of the status is based on the other command.

16. The host system of claim 14, wherein, to obtain the message from the memory apparatus, the one or more components are configured to:
obtain a portion of the data via a pin of one or more pins of a bus between the host system and the memory apparatus; and
obtain a portion of the status via the pin.

17. The host system of claim 14, wherein the one or more components are further configured to:
provide, to the memory apparatus, another command indicating a location configuration for the status, wherein the other command further indicates that the memory apparatus is to store a value indicating the location configuration to one or more mode registers of the memory apparatus.

18. The host system of claim 14, wherein the one or more components are further configured to:
provide, to the memory apparatus, another command indicating that the memory apparatus is to reset the one or more fault mode registers.

19. The host system of claim 14, wherein the message comprises a data burst packet.

20. A system, comprising:
a host system;
a memory apparatus;
a host interface between the host system and the memory apparatus; and
one or more components configured to:
communicate, via the host interface and to the memory apparatus, a command indicating that the memory apparatus is to provide data to the host system;
identify, by the memory apparatus, a status of one or more fault mode registers based on the command; and
communicate, via the host interface and to the host system, a message comprising the data and comprising the status of the one or more fault mode registers.

21. The system of claim 20, wherein the memory apparatus is configured to:
detect one or more faults associated with the memory apparatus; and
store, to the one or more fault mode registers, respective values indicating the one or more faults, wherein the status of the one or more fault mode registers is based on the respective values.

22. The system of claim 21, wherein the one or more components are further configured to:
communicate, via the host interface and to the memory apparatus, a configuration command associated with the one or more fault mode registers; and
selectively, based on the configuration command, include a subset of the respective values in the message.

23. The system of claim 20, wherein, to communicate the message, the one or more components are configured to:
communicate a portion of the data via a pin of one or more pins of the host interface; and
communicate a portion of the status via the pin.

24. The system of claim 20, wherein the one or more components are configured to:
communicate, via the host interface and to the memory apparatus, another command to initiate a fault monitoring mode; and
store a value indicating the fault monitoring mode to one or more mode registers of the memory apparatus, wherein identification of the status is based on the value indicating the fault monitoring mode.

25. The system of claim 20, wherein the one or more components are configured to:
communicate, via the host interface and to the memory apparatus, another command indicating a location configuration for the status; and
store a value indicating the location configuration to one or more mode registers of the memory apparatus.
